(19) United States
(12) Patent Application Publication
(10) Pub. No.: US 2016/0336736 A1
(43) Pub. Date: Nov. 17, 2016

(54) METHOD FOR DETECTING AN ABNORMALITY IN A RELAY

(71) Applicant: KABUSHIKI KAISHA TOYOTA JIDOSHOKKI, Kariya-shi, Aichi (JP)

(72) Inventors: Hiroyuki NOMURA, Aichi (JP); Kenji NISHIGAKI, Aichi (JP); Takahiro TSUZUKU, Aichi (JP)

(73) Assignee: KABUSHIKI KAISHA TOYOTA JIDOSHOKKI, Kariya-shi, Aichi (JP)

(21) Appl. No.: 15/107,659

(22) PCT Filed: Dec. 4, 2014
(86) PCT No.: PCT/JP2014/082109

§ 371 Date: Jun. 23, 2016

(30) Foreign Application Priority Data
Dec. 24, 2013 (JP) 2013-265079

(51) Int. Cl. H02H 7/18; G01R 31/36; G01R 31/327; H02J 7/00

(52) U.S. Cl. CPC H02H 7/18; H02J 7/0021; G01R 31/3658; G01R 31/3278; H02J 7/0031

(57) ABSTRACT

A method for detecting an abnormality in a relay that can detect that a module relay is inoperative is provided. In a method for detecting an abnormality in a relay in a battery pack comprising a plurality of battery modules connected in parallel to each other and comprising a main relay and module relays, the main relay is shut off if it is determined that a current is flowing in a battery module for which the module relay is not shut off and a current is flowing in a battery module for which the module relay is shut off.

### TECHNICAL FIELD

The present invention relates to a method for detecting an abnormality in a relay and in particular to a relay of a battery pack.

### BACKGROUND ART

In regard to a vehicle which mounts a plurality of battery modules and moves by utilizing electricity, such a construction is known where a module relay is provided for each battery module and controlled independently. For example, Patent Document 1 describes a control wherein connection states for a plurality of battery devices are changed in response to failure states. Also, such a control is known where, if a battery cell becomes abnormal, a module relay of the battery module including the battery cell is shut off and a limp-home operation is performed by using another battery module.

### CONVENTIONAL ART DOCUMENTS

### Patent Documents

### [Patent Document 1] Japanese Patent Application Laid Open No. 2011-41386

### SUMMARY OF THE INVENTION

### Problems to be Solved by the Invention

However, conventional techniques have a problem that, if a module relay per se is inoperative due to some abnormality, the abnormality might not be detected. As a result, for example, there may be a possibility that safety of the vehicle cannot be assured.

The present invention is made in order to solve this problem and is aimed at providing a method for detecting an abnormality in a module relay if the module relay per se is inoperative due to some abnormality.

### Means for Solving the Problems

In order to solve the above problem, a method for detecting an abnormality in a relay related to the present invention is a method for detecting an abnormality in a relay of a battery pack, the battery pack comprising a plurality of battery modules, the battery modules being connected in parallel to each other, a main relay being provided in relation to the battery pack, each battery module comprising a module relay, wherein the method comprises:

a step for shutting off the main relay if it is determined that a current is flowing in a battery module for which the module relay is not shut off and a current is flowing in a battery module for which the module relay is shut off.

According to this invention, determination is performed based on the state of currents in a plurality of battery modules.

### Effect of the Invention

The present invention can detect, or can detect more precisely, that a module relay is inoperative due to some abnormality by performing determination based on the state of currents in a plurality of battery modules.

### BRIEF DESCRIPTION OF THE DRAWINGS

FIG. 1 is a diagram showing an exemplary construction of a battery pack related to a first embodiment of the present invention.

FIG. 2 is a flow chart showing an operational flow of the battery ECU and the monitoring ECU of FIG. 1.

FIG. 3 is a graph representing examples of output values from a current sensor of FIG. 1.

### EMBODIMENTS OF THE INVENTION

Embodiments of the present invention will be explained below with reference to the attached drawings.

### First Embodiment

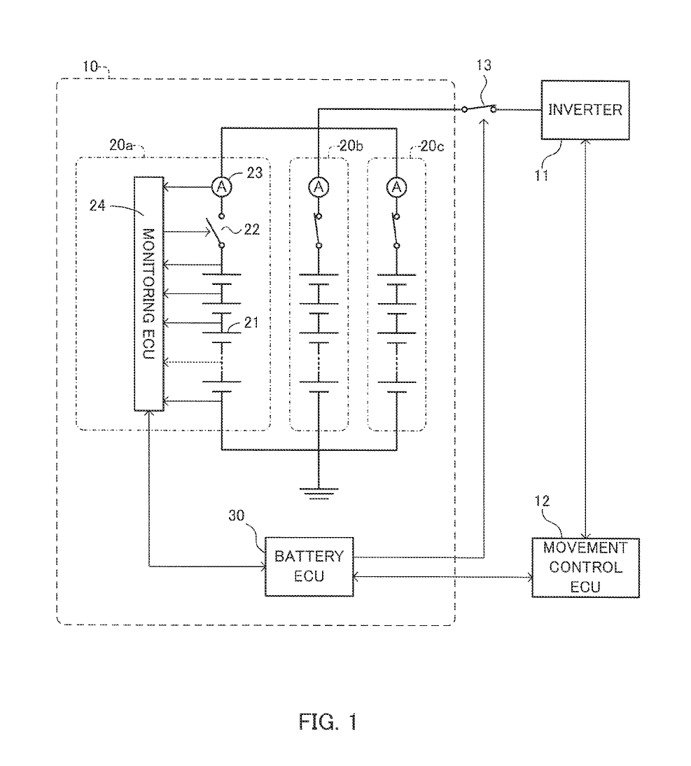

FIG. 1 shows an exemplary construction for carrying out a method for detecting an abnormality of a relay in a battery pack related to a first embodiment of the present invention. The present method is carried out in relation to a battery pack 10. The battery pack 10 is, for example, mounted to a vehicle and transfers electric power to/from a motor generator (not shown) via an inverter 11.

A main relay 13 is provided in relation to the battery pack 10. The main relay 13 is located, for example, between the battery pack 10 and the inverter 11. In a state wherein the main relay 13 is conducting, electric power can be transferred between the battery pack 10 and the inverter 11. In a state wherein the main relay 13 is shut off (i.e. a state wherein the main relay 13 is not conducting), no electric power is transferred between the battery pack 10 and the inverter 11.

Also, a travel control ECU 12 for controlling the battery pack 10 (in particular, the battery ECU 30 described below) and the inverter 11 is provided so as to be communicable with them.

The battery pack 10 comprises a battery ECU 30 for controlling the battery pack 10. Also, the battery pack 10 comprises a plurality of battery modules 20 (20a-20c) and the battery ECU 30 controls the battery modules 20. Further, the battery ECU 30 is connected to the main relay 13 and controls the open/close operation of the main relay 13.

The battery modules 20 are connected in parallel to each other. Also, in the present embodiment, the main relay 13 is connected to the battery modules 20 in series with each of them. Each of the battery modules 20 comprises one or more battery cells 21, a module relay 22 and a current sensor 23. In each battery module 20, the battery cells 21, the module relay 22 and the current sensor 23 are connected in series.

Each battery module 20 comprises a monitoring ECU 24. Although the monitoring ECU 24 is shown with respect to the battery module 20a only in FIG. 1, the other battery modules 20b and 20c also comprise similar monitoring ECUs. The monitoring ECU 24 monitors the state of the battery module 20, communicates with the battery ECU 30 and controls the battery module 20 in response to instructions from the battery ECU 30 (detailed operations of the monitoring ECU 24 will be described later). Thus, in the present embodiment, the monitoring ECU 24 and the battery ECU 30 constitute control means for controlling operation of the battery pack 10.

The monitoring ECU 24 is connected to the two terminals of each battery cell 21 so that a voltage between the terminals can be measured for each battery cell 21. Also, the monitoring ECU 24 is connected to the current sensor 23 so that a current flowing in the battery module 20 (more precisely, a current flowing in the battery cells 21) can be measured. Also, the monitoring ECU 24 is connected to the module relay 22 and controls open/close operation of the module relay 22.

In the battery pack 10 constructed as described above, the control means including the monitoring ECU 24 and the battery ECU 30 operates as follows.

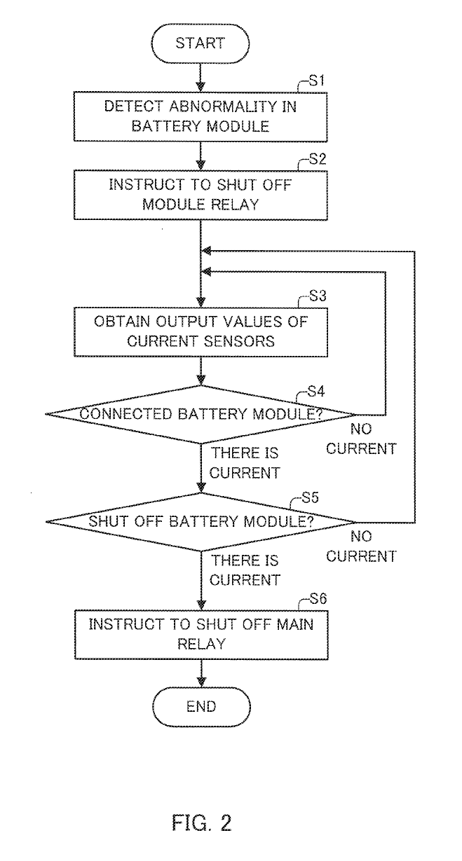

FIG. 2 is a flow chart showing an operational flow of the control means. A process shown in this flow chart is started in response to the control means detecting an abnormality in the battery module 20 (Step S1). In Step S1, the battery ECU 30 detects that an abnormality occurred in the battery module 20 based on information of a voltage and/or a current of the battery transmitted from the monitoring ECU 24.

In the example explained below, an abnormality is detected in the battery module 20a. If the abnormality is detected in the battery module 20, the control means shuts off the module relay 22 in the battery module 20 wherein the abnormality is detected (Step S2). In Step S2, the battery ECU 30 instructs the monitoring ECU 24 to shut off the module relay 22 of the battery module 20a. In response to this instruction, the monitoring ECU 24 issues an instruction to shut off the module relay 22, thereby the module relay 22 is shut off.

The battery ECU 30 may communicate with the travel control ECU 12 in relation to Step S2. For example, the travel control ECU 12 receives an abnormality signal from the battery ECU 30 and starts a limp-home operation in response to this. Also, the travel control ECU 12 may perform an alarm display for a driver or vehicle speed restriction.

Next, the control means obtains, for all the battery modules 20, information representative of whether a current is flowing therein (Step S3). In the present embodiment, the information is a current value detected by the current sensor 23. In Step S3, all the monitoring ECUs 24 receive the current values from respective current sensors 23 and transmit the current values to the battery ECU 30. The battery ECU 30 receives the current values from the monitoring ECUs 24.

Next, the control means determines whether a current is flowing in each battery module 20 (Steps S4 and S5). In particular, the battery ECU 30 determines whether a current is flowing in any of the battery modules 20 for which the module relays 22 are not shut off (i.e. connected battery modules; battery modules 20b and 20c in this example) and a current is flowing in the battery module 20 for which the module relay 22 is shut off (more precisely, the battery module 20 with respect to which it is instructed to shut off the module relay 22; the battery module 20a in this example).

Here, since it has been instructed for the module relay 22 of the battery module 20a to shut off in Step S2, the module relay 22 may be inoperative due to some abnormality if a current is flowing in the battery module 20a. On the other hand, if no current is flowing in the battery module 20a (and, in particular, if a current is flowing in the battery module 20b or 20c), the module relay 22 of the battery module 20a can be considered to be operating normally.

If it is determined that a current is flowing in any of the battery modules for which the module relays 22 are not shut off and a current is flowing in the battery module for which the module relay 22 is shut off, the control means shuts off the main relay 13 (Step S6). In Step S6, the battery ECU 30 issues an instruction to shut off the main relay 13, thereby the main relay 13 is shut off.

Otherwise (that is, if it is determined that no current is flowing in any of the battery modules for which the module relay 22 is not shut off or it is determined that no current is flowing in the battery module for which the module relay 22 is shut off), process of the control means returns to Step S3. That is, in this case, the main relay 13 is not shut off.

In Steps S4 and S5, those skilled in the art can design a specific determination criterion as to whether the current is flowing. For example, the determination criterion may be whether the current value is zero, whether the current value is less than a detection limit, whether the current value is less than a predetermined threshold, etc.

Thus, the control means shuts off the main relay 13 if a current is flowing in the battery module 20 for which the module relay 22 has been instructed to be shut off, so the control means can detect the abnormality in the module relay 22 and carry out a fail-safe process.

Not that, in accordance with the determination in Step S4, the main relay 13 would not be shut off if no current is flowing in the battery module 20 for which the module relay 22 is not shut off, so malfunctioning (for example, due to an error of the current sensor 23 caused when no battery module 20 is operating) can be avoided.

Such a fail-safe process is required or beneficial in, for example, a limp-home operation in the case of excessive charging or discharging abnormality, a limp-home operation in the case of communication abnormality, and a limp-home operation in the case of other abnormalities in a battery control system, etc. Further, such a fail-safe process may be necessary or beneficial not only when there are abnormalities but also when there is degradation of the battery cells 21 or growth of battery capacity difference among the battery cells 21.

The following modifications can be made to the first embodiment. In the first embodiment, the information representative of whether a current is flowing or not is the current value detected by the current sensor 23. In an alternative, the information representative of whether a current is flowing or not may be a time derivative value of the current value. For example, the main relay 13 is shut off if a time derivative value of the current value in any of the battery modules for which the module relays 22 are not shut off is equal to or greater than a predetermined threshold and a time derivative value of the current value in the battery module for which the module relay 22 is shut off is equal to or greater than the threshold.

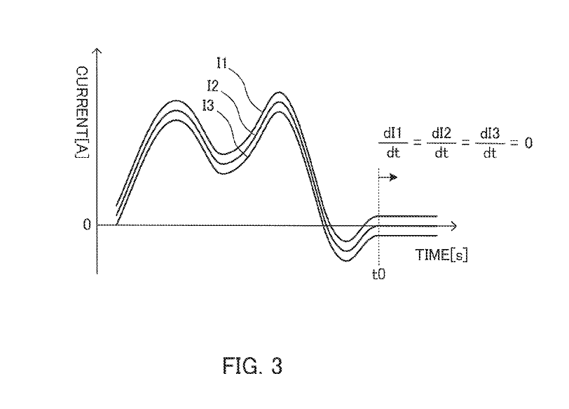

Effects of an error in the current sensor 23 can be suppressed by using the time derivative value of the current value. FIG. 3, which is a graph explaining this, shows examples of output values from three current sensors measuring the same current. The output values from the three current sensors are denoted by I1, I2 and I3. The actual current is supposed to be zero after time instant t0. The output value I2 indicates the correct value whereas the output value I1 includes a positive error (zero drift) and the output value I3 includes a negative error.

Even if the current sensors including errors are used, all time derivatives of the output values would be zero after the time instant t0 where the current value becomes constant at zero, so the determination can be precise regardless of the error in the current sensors.

Also, the information representative of whether a current is flowing or not may be a terminal voltage of the battery cell 21. If a current flows in the battery cell 21, its terminal voltage would vary due to the internal resistance. On the other hand, if no current flows in the battery cell 21, the variation due to the internal resistance would not appear. Accordingly, the determination may be carried out based on the terminal voltage.

In the first embodiment, only the main relay 13 is shut off in accordance with the determinations in Steps S4 and S5. In an alternative, any or all of the module relays 22 may be shut off in addition to the main relay 13. That is, if it is determined that a current is flowing in the battery module 20 for which the module relay 22 is not shut off and a current is flowing in the battery module for which the module relay 22 is shut off, all module relays 22 may be shut off in addition to the main relay 13. In such an alternative, reflux among the battery modules 20 can be prevented so that safety would be improved. This effect is remarkable in particular in a construction wherein the plurality of battery modules 20 are connected in parallel as shown in FIG. 1.

In the first embodiment, all battery modules 20 are connected in parallel to each other. However, if at least two battery modules 20 are connected in parallel, an additional battery module connected in series with any of them may be provided.

In the first embodiment, all battery modules 20 are subject to determination in Step S3. However, more precisely, it would be sufficient for carrying out the present invention if all battery modules 20 for which the module relays 22 are shut off and at least one of the battery modules 20 for which the module relays 22 are conducting are subject to the determination.

In the first embodiment, the control means shuts off the module relay 22 in Step S1 if the control means detects an abnormality in the battery module 20. In an alternative, the control means may shut off the module relay 22 even if the battery module 20 is normal. For example, the present method may be carried out for each of the module relays 22 of the battery modules 20a-20c sequentially. In this way, an abnormality in the module relays 22 can be detected before detection of any abnormality in the battery modules 20, so safety would be improved further.

1. A method for detecting an abnormality in a relay of a battery pack, the battery pack comprising a plurality of battery modules, the battery modules being connected in parallel to each other, a main relay being provided in relation to the battery pack, each battery module comprising a module relay, wherein the method comprises:
a step for shutting off the main relay if it is determined that a current is flowing in a battery module for which the module relay is not shut off and a current is flowing in a battery module for which the module relay is shut off.

2. Themethod of claim 1, whereinthemethodfurthercomprises:
a step for shutting off all said module relays if it is determined that the current is flowing in the battery module for which the module relay is not shut off and the current is flowing in the battery module for which the module relay is shut off.

3. The method of claim 1, wherein the determination as to whether the current is flowing in each battery module is carried out based on a time derivative value of a current value.

4. The method of claim 1, wherein:
the main relay is connected in series with each battery module;
each battery module comprises at least one battery cell; and
the battery cells are connected in series with the module relay in each battery module.
